(19) United States
(12) Patent Application Publication
(10) Pub. No.: US 2016/0172527 A1
(43) Pub. Date: Jun. 16, 2016

(54) Photodetector with Interdigitated Nanoelectrode Grating Antenna

(71) Applicant: Sandia Corporation, Albuquerque, NM (US)

(72) Inventors: Thomas Edwin Beechem, III, Albuquerque, NM (US); Stephen W. Howell, Albuquerque, NM (US); David W. Peters, Albuquerque, NM (US); Paul Davids, Albuquerque, NM (US); Eric A. Shaner, Rio Rancho, NM (US)

(21) Appl. No.: 15/017,847

(22) Filed: Feb. 8, 2016

Related U.S. Application Data
(63) Continuation-in-part of application No. 14/056,023, filed on Oct. 17, 2013, now Pat. No. 9,293,627.
(60) Provisional application No. 61/732,667, filed on Dec. 3, 2012.
(60) Provisional application No. 62/114,146, filed on Feb. 10, 2015.

(51) Int. Cl. H01L 31/113; H01L 31/0232

(52) U.S. Cl. CPC H01L 31/1136; H01L 31/02327

(57) ABSTRACT

An interdigitated nanoelectrode grating functions both as an absorption-enhancing sub-wavelength antenna and to minimize the distance between electron-hole creation and current collection so as to enhance photodetection schemes based upon active layers comprising two-dimensional semiconducting materials.

### CROSS-REFERENCE TO RELATED APPLICATION

This application is a continuation-in-part of U.S. application Ser. No. 14/056,023, filed Oct. 17, 2013, which claims the benefit of U.S. Provisional Application No. 61/732,667, filed Dec. 3, 2012, both of which are incorporated herein by reference. This application also claims the benefit of U.S. Provisional Application No. 62/114,146, filed Feb. 10, 2015, which is incorporated herein by reference.

### STATEMENT OF GOVERNMENT INTEREST

This invention was made with Government support under contract no. DE-AC04-94AL85000 awarded by the U. S. Department of Energy to Sandia Corporation. The Government has certain rights in the invention.

### FIELD OF THE INVENTION

The present invention relates to photodetectors and, in particular, to a photodetector with interdigitated nanoelectrode grating antenna.

### BACKGROUND OF THE INVENTION

Typical infrared sensor materials are composed of complex semiconductors, such as HgCdTe (MCT) and InGaAs, that are utilized both as a consequence of their bandgap being commensurate with infrared (IR) wavelengths and their ability to tune this gap over a spectral range based upon the material's composition. Such tunability is realized, however, only during design as the composition of the detectors and, therefore, the bandgap is fixed upon their fabrication. Dynamic, real-time tunability, in contrast, would enable multi-color operation as well as the flexibility to optimize based upon differing operational imperatives.

Graphene is a two-dimensional layered material only an atom thick having optical, thermal, and electrical properties that are intriguing for sensing. To this end, demonstrations of graphene detectors have shown promise, including bandwidths >200 GHz, comparatively large sensitivities, broadband absorption, and spectral tunability. See D. Sun et al., Nature Nanotechnology 7, 114 (2012); A. Urich et al., Nano Letters, 2804 (2011); F. Xia et al., Nature Nanotechnology 4, 839 (2009); T. Mueller et al., Nature Photonics 4, 297 (2010); F. Xia et al., Nano Letters 9, 1039 (2009); T. J. Echtermeyer et al., Nat Commun 2, 458 (2011); V. Ryzhii and M. Ryzhii, Physical Review B 79, 245311 (2009); Y. Liu et al., Nat Commun 2, 579 (2011); R. R. Nair et al., Science 320, 1308 (2008); Y. Zhang et al., Nature 459, 820 (2009); and J. Yan et al., Nature Nanotechnology 7, 472 (2012). Furthermore, because graphene devices exhibit very low noise characteristics, graphene-based photodetectors can operate with reduced cooling requirements. See Y. Lin and P. Avouris, Nano Letters 8, 2119 (2008); and V. Ryzhii and M. Ryzhii, Physical Review B 79, 245311 (2009). Other two-dimensional semiconducting layered materials including molybdenum disulphide (MoS₂), tungsten disulphide (WS₂), gallium selenide (GaSe), and heterogeneous combinations of these materials have also shown promise towards these ends. See Choi et al., Advanced Materials 24, 5832 (2012), Lei et al., Nanoletters 13, 2777 (2013); and Koppens et al., Nature Nanotechnology 9, 780 (2014).

Bilayer graphene (BLG) offers advantages that its more common form, monolayer graphene (MLG), does not. Most prominently, a dynamic, tunable bandgap can be readily induced in BLG from the near infrared to THz using only electrical fields. See Y. Lin and P. Avouris, Nano Letters 8, 2119 (2008); F. Xia et al., Nature Nanotechnology 4, 839 (2009); and Y. Zhang et al., Nature 459, 820 (2009), which are incorporated herein by reference. This ability to tune the bandgap with only solid-state technology enables faster, filter-less and more sensitive multispectral and hypertemporal imaging applications. Practically realizing these advantages, however, requires the ability to fabricate a tunable BLG device and a means to increase the absorption within this atomically thin material, which absorbs less than 5% of the incident light.

Despite the promise of photodetection using an active layer of two-dimensional materials, the state of the art suffers from two major deficiencies: (1) lack of absorption stemming from the atomic thinness of the active material, and (2) absorption enhancing mechanisms limit the utility of the device. With respect to the former, sub-wavelength structures (“nanoantennas”) have been successfully utilized to increase absorption by >15× in both graphene and other two-dimensional structures. See T. J. Echtermeyer, Nature Communications 2, 458 (2011). Most often, however, these nanoantennas are a wholly separate device element serving only to enhance the optical characteristics. At times, their presence may even increase the distance between the creation of electron-hole pairs and their collection, thereby reducing the quantum efficiency of the photodetector. Taken together, it is therefore apparent that while nanoantennas make absorption within a two-dimensional material strong enough as to make the device tractable, their presence is oftentimes disadvantageous to the electro-optic response of the photodetector.

Therefore, a need remains for an infrared photodetector comprising a sub-wavelength antenna that enhances the absorption of the active material layer, yet provides efficient collection of charge carriers.

### SUMMARY OF THE INVENTION

The present invention is implementation of an interdigitated electrode architecture that is designed to function as both an absorption-enhancing nanoantenna and to minimize the distance between electron-hole creation and current collection so as to enhance photodetection schemes based upon active layers comprising two-dimensional semiconducting materials. Each of the source, drain, and gate electrodes serve not only as electrical contacts but also as the sub-wavelength nanoantenna. The surface mode coupling sub-wavelength antenna resonantly couples with the incident light in such a way to greatly enhance absorption in the active layer.

The photodetector comprises a two-dimensional semiconducting active layer on a substrate; interdigitated source and drain terminals comprising a periodic array of pairs of source and drain fingers deposited on the front side of the active layer; a gate dielectric layer deposited on front side of the active layer and the interdigitated source and drain terminals; a top-gate terminal deposited on the gate dielectric layer, the top-gate terminal comprising a periodic array of gate fingers, each gate finger disposed between a pair of source and drain fingers and thereby forming a channel region therebetween, wherein the gate fingers are electrically connected; and wherein the interdigitated source and drain terminals, gate dielectric layer, and top-gate terminal are adapted to provide a nanoantenna that enhances absorption of incident light in the active layer, thereby enabling photodetection of the incident light. The periodic array of pairs of source and drain fingers can have a periodicity of less than one-third and preferably less than one-tenth the wavelength of the incident light. The incident light can have a wavelength between 300 nanometers and 30 microns. The width of the channel region formed between each pair of source and drain fingers can be less than 10 μm. The active layer can comprise a two-dimensional semiconducting material, such as bilayer graphene. The bandgap of the bilayer graphene can be tunable from the mid-infrared (approximately 5 microns wavelength) to terahertz regime of the incident light. Alternatively, the active layer can comprise monolayer graphene, molybdenum disulphide, tungsten disulphide, or gallium selenide. The gate dielectric layer can comprise SiO₂, Al₂O₃, Si₃N₄, or HfO₂, or any other dielectric material and have a thickness less than 150 nanometers. The photodetector can further comprise a conductive back gate disposed on the backside and insulated from the active layer for applying an electric field with the top-gate terminal across the active layer, thereby forming a dual-gated field-effect transistor. The photodetector can further comprise a back metal reflector on the back side of the active layer for further enhancing absorption in the active layer.

When bilayer graphene is the active material, the bilayer graphene layer can comprise epitaxial graphene grown on a semi-insulating silicon carbide substrate. The conductive back gate can comprise a region of conductive ions implanted in the semi-insulating silicon carbide substrate. Alternatively, the conductive back gate can comprise a highly doped silicon carbide substrate and the semi-insulating substrate can comprise an undoped silicon carbide layer grown on the highly doped silicon carbide substrate. Alternatively, the semi-insulating silicon carbide substrate can be back-thinned and a metal layer can be deposited on the backside of the back-thinned silicon carbide substrate to provide the conductive back gate and a back metal reflector. Alternatively, the bilayer graphene can be synthesized via other methods, for example chemical vapor deposition, and transferred to arbitrary substrates that can be back-gated using standard approaches.

### BRIEF DESCRIPTION OF THE DRAWINGS

The detailed description will refer to the following drawings, wherein like elements are referred to by like numbers.

FIG. 1A is a schematic illustration of the electronic band structure of monolayer graphene. FIG. 1B shows the electronic band structure of bilayer graphene.

FIG. 2A is a top-view and FIG. 2B is a side-view schematic illustration of a photodetector comprising a nanoantenna grating with as interdigitated electrode configuration.

FIG. 3 is a graph showing the modification of absorption in a nanoantenna grating (1 μm period) when every other finger is offset vertically by a distance specified by the top-gate dielectric layer.

FIGS. 4A-4C show examples of tunable photodetectors that integrate bilayer graphene with a top-side sub-wavelength nanoantenna that functions both as a means to increase absorption and as a interdigitated field-effect transistor. FIG. 4A is a side-view schematic illustration of an embodiment wherein a semi-insulating SiC wafer that is ion implanted beneath the contact and electrically contacted using the reflective backplane for the nanoantenna.

FIG. 4B is a side-view schematic illustration of an embodiment wherein the back-gate is formed by utilizing an epitaxially grown doped SiC substrate that rests on semi-insulating epitaxial layer of SiC. FIG. 4C is a side-view schematic illustration of an embodiment wherein a semi-insulating SiC substrate is etched back allowing for metal deposition near the bilayer graphene to provide a back electrical contact and reflective backplane.

### DETAILED DESCRIPTION OF THE INVENTION

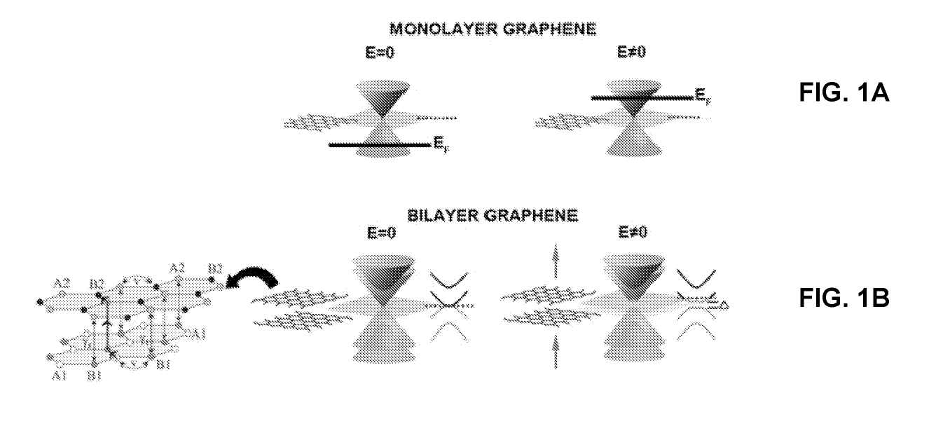

Monolayer graphene (MLG) is a semi-metal for which at typical pixel sizes it is impossible to create a bandgap. Thus, while previous work has demonstrated MLG's promise as an ultrafast and efficient photodetector, the material's nearly constant broadband response effectively removes any possibility for its use as a filter-less multispectral detector. See F. Xia et. al., Nature Nanotechnology 4, 839 (2009); F. Xia et al., Nano Letters 9, 1039 (2009); and R. R. Nair et al., Science 320, 1308 (2008). MLG's lack of bandgap arises due to its unique electronic structure characterized by two cones that intersect at the Dirac point, which is typically near the Fermi energy (E_{F}), as shown in FIG. 1A. Upon application of a transverse electric field (i.e., E≠0), only the Fermi energy changes and no bandgap forms. Bilayer graphene, on the other hand, has four distinct bands that arise due to the sublattice that is created by the inequivalent sites (A1 vs. A2 and B1 vs. B2 in FIG. 1B) between two hexagons stacked in a Bernal arrangement. Upon the application of an electric field (i.e., E≠0) perpendicular to the layers, the symmetry between these inequivalent sites is removed thereby inducing a bandgap Δ in the electronic structure. Previous work has shown through FTIR spectroscopy that this band can be tuned using only electronic fields. See Y. Zhang et al., Nature 459, 820 (2009).

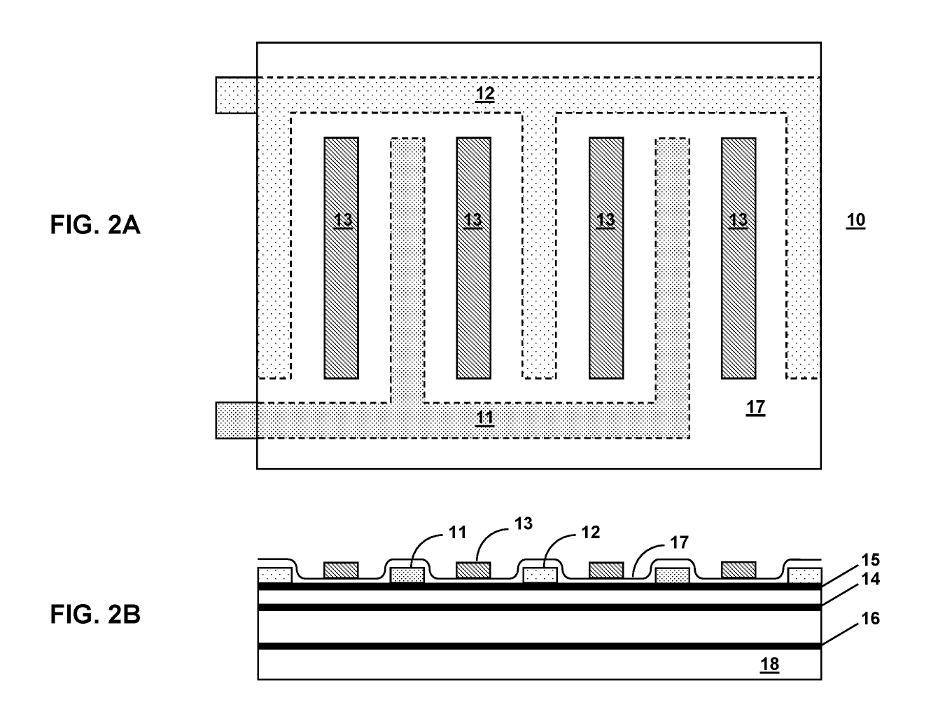

The present invention is directed to a tunable photodetection enabled by a thin active material layer that has viable quantum efficiencies through the utilization of an absorption augmenting nanoantenna with an integrated interdigitated electrode configuration, as shown in FIGS. 2A and 2B. The photodetector integrates an absorption enhancing nanoantenna 10 that also provides the electrical contacts, namely the interdigitated source 11, drain 12, and top-gate 13 electrodes. Incorporation of metallic top 13 and bottom 14 gate structures (i.e., dual gates) provides for the application of both the transverse electric field that induces a bandgap in the active BLG layer 15, as well as control of the Fermi energy's position within the created gap. To enhance the absorption, the top gate 13 can be coupled with a reflecting backplane 16 that can either serve as the bottom gate itself or be located directly behind the bottom gate 14. The locations of the gates 13, 14 and reflector 16 are important for optimizing the strength of the electric field across the BLG 15 (maximizing bandgap magnitude) and for optimizing the absorption. BLG has a bandgap that is tunable from the mid-wavelength infrared (about 5 μm wavelength) into the THz regime. Nanoantennas can be fabricated for this portion of the electromagnetic spectrum using standard lithographic techniques. The invention fully leverages the differentiating material advantages of BLG—low-noise, high-speed, and a tunable bandgap controlled via electric fields—to create a photodetector capable of switching spectral bands while maintaining sensitivities comparable to state-of-the-art. The interdigitated electrode structure 10 is also applicable to other photodetectors utilizing ultrathin (e.g., <50 nm), two-dimensional semiconducting active layers. Therefore, the active layer 15 can alternatively comprise other two-dimensional semiconducting layered materials, such as MoS₂, WS₂, GaSe, or heterogeneous combinations thereof.

To fabricate the nanoantenna 10, source 11 and drain 12 metal can be deposited on top of the active layer 15 on a substrate 18 using standard optical, or e-beam lithography and lift-off, followed by the deposition of a thin gate dielectric layer 17. The patterned nanoantenna can be made from a metal or other highly conductive material, such as a highly doped semiconductor. With metals, such as aluminum or gold, the thickness of the fingers can be about 100 nm. The periodicity of the antenna is sub-wavelength and, preferably, between ⅓ and 1/10 the wavelength λ of the incident light. The source 11 and drain 12 can form pairs of interdigitated terminal fingers that are spaced less than ⅓ the center wavelength of interest apart (e.g., ˜100 nm for visible region to ˜4.5 μm for infrared sensing). The spacing is selected to maintain reasonable carrier extraction while at the same time maximizing absorption. The gate dielectric layer 17 preferably is transparent to the wavelength of the incident light. For example, the gate dielectric material can be SiO₂, Al₂O₃, Si₃N₄, or HfO₂, although other suitable dielectric materials can also be used. A top-gate terminal 13 can be patterned in photoresist and deposited on the dielectric layer 17 with a metal liftoff process. The top-gate 13 can comprise a periodic array of gate fingers, each gate finger disposed between a source-drain finger pair and separated therefrom by the dielectric. The gate fingers can be electrically contacted using vias (not shown) to enable the top-gate terminal 13 to also be used as a top-gate electrode. The interdigitated source and drain terminals 11, 12 and the top-gate array 13 thereby provide a nanoantenna grating. Alternatively, the active layer can rest on top of a dielectric and can be gated from the bottom by a back-gate and the source/drain electrodes alone can form a resonant structure.

The invention provides two significant advantages over prior photodetectors. First, the contact layout is designed such that nearly the entire active area of the photodetector is the nanoantenna. Thus, enhanced absorption can be induced over the entirety of the device rather than just the top-gate region. Second, the interdigitated, multi-finger architecture minimizes the source to drain spacing thereby increasing the likelihood of e-h pairs entering the circuit before recombination.

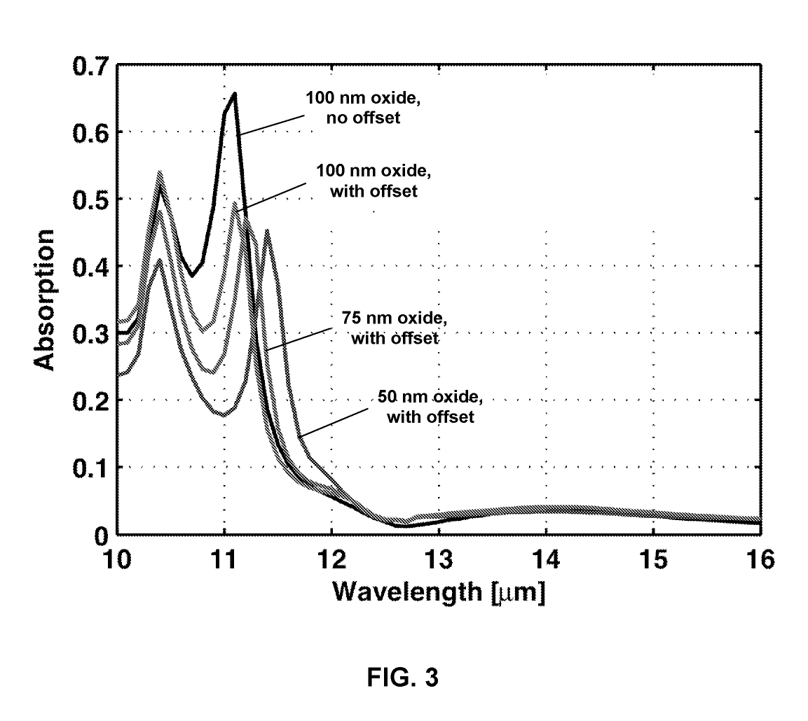

The basic geometry of prior nanoantennas is changed due to the integration of the source and drain contacts into the optical design. Practically, this manifests itself as a vertical offset between the various source 11, drain 12, and gate 13 fingers making up the nanoantenna grating as a result of the necessities of electronically operating the device. For example, the source 11 and drain 12 must be in intimate contact with the active layer 15 as this is where carriers from the active layer are swept out into the circuit. The gate 13, on the other hand, applies a voltage to the active layer 15, but it must be isolated electrically so as to avoid a current path. This isolation is realized through the deposition of the thin gate dielectric layer 17. From an optical perspective, this means that the grating will have a vertical offset of ˜10-150 nm for every other finger. To assess the ramifications of this offset, a rigorous coupled-wave analysis (RWCA) simulation was performed having topologies where the degree of offset was varied. As shown in FIG. 3, the offset does have an effect on the spectral response of the nanoantenna for an exemplary SiC, graphene, SiO₂ stack. Spectral changes in peak absorption are observed; however, the qualitative response is similar for the various topologies. Most importantly, the change in spectral response is not so strong as to render the nanoantenna ineffective. Furthermore, comparisons of the absorption when the graphene is tuned “on” and “off” indicate that this offset does not disrupt the ability for the nanoantenna grating to couple light into the graphene.

The photodetector of the present invention can have a channel length on the order of ˜1 μm rather than the ˜10 μm channel widths used previously when a nanoantenna is utilized as a separate optical element. To quantify the effect of shortening the channel width, the transit time of a photogenerated electron can be compared to previous measurements of the intrinsic response time of a monolayer graphene photodetector (e.g., 2.1 ps). In this way the internal quantum efficiency can be determined as a function of channel length. See A. Urich et al., Nano Letters, 2804 (2011). The transit time can be estimated according to tₜ=I²I(μV_{SD}) where I is considered to be the maximum source to drain spacing, μ is the channel mobility of the BLG, and V_{SD} is the voltage difference from source to drain. Assuming a measured mobility of a graphene film (similar methods can be utilized for other ultrathin materials) of 4400 cm²/V, a modest applied bias of 0.1 V, and a channel spacing of 1.5 μm, the average transit time is estimated to be 17 ps. See K. Lee et al., Nano Letters 11, 3624 (2011). This fact, combined with the large absorption coming from the nanoantenna and photoinduced gain due to the interdigitated field-effect transistor (FET) architecture, provides the present invention with large sensitivity. See V. Ryzhii and M. Ryzhii, Physical Review B 79, 245311 (2009).

### BLG-Based Tunable IR Photodetector Embodiments

Described below are exemplary embodiments and methods of fabricating tunable BLG FETs having integrated nanoantennas with interdigitated electrodes. The primary difference in the three embodiments is the method used to form a back gate contact and back reflector.

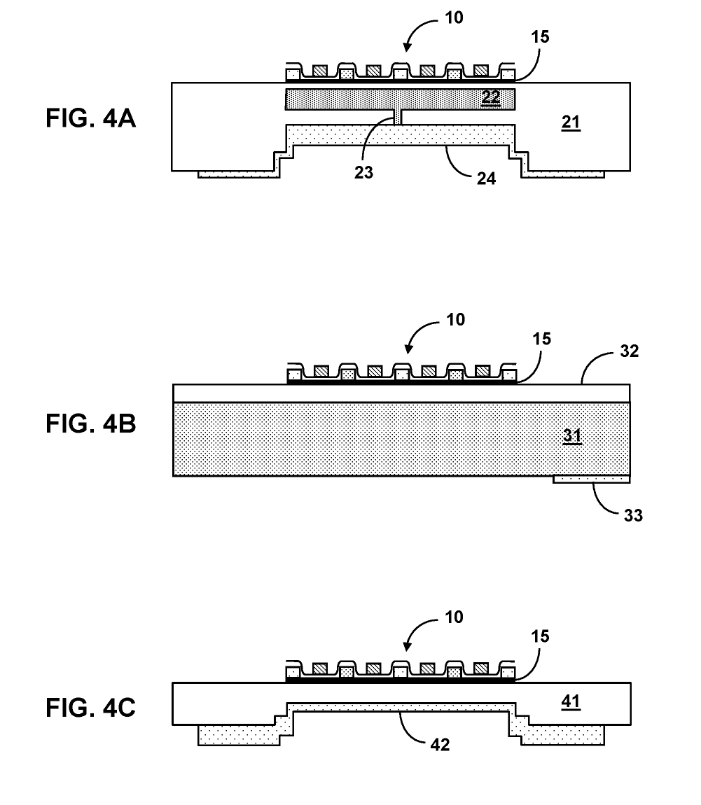

FIG. 4A is a schematic illustration of an embodiment wherein a semi-insulating silicon carbide wafer is ion implanted beneath the contact and electrically contacted using the reflective backplane for the nanoantenna. To fabricate this embodiment, a semi-insulating silicon carbide (SiC) substrate 21 can be implanted with conductive ions to form a conductive back gate 22 and via 23 for later connection to a backside metal contact 24. This implantation approach is similar to that performed by Waldman et al. who used N ions to form the back gate of an epitaxial based graphene FET. See D. Waldmann et al., Nat Mater 10, 357 (2011), which is incorporated herein by reference. To ease the required implantation conditions and maximize the effectiveness of the back metal reflector 24, the SiC 21 can be first thinned to a distance of ˜¼ λ from the BLG layer 15 using SF₆/O₂ to form a graphene/SiC mesa. Ion implantation can then be performed underneath the mesa in order to locate the back gate 22 about 100 nm away from the graphene 15. After implantation, the back side can be coated with metal to form both the reflector 24 and to provide electrical contact to the bottom gate via 23. On the top side, source and drain metals and of the nanoantenna 10 can be deposited using standard optical lithography and lift-off, followed by the deposition of a thin (e.g., ˜50 nm) gate dielectric layer. The dielectric material preferably is transparent to the wavelength of the incident radiation and has a large DC dielectric constant to facilitate the opening of the bandgap. For example, the dielectric material can be SiO₂, Al₂O₃, Si₃N₄, or HfO₂, although other suitable dielectric materials can also be used. Upon this dielectric layer, the top gate can be patterned in photoresist and deposited with a metal liftoff process. The structures shown in FIGS. 4B and 4C are similar in many of the process steps to those described above. In FIG. 4B, for example, the implant step is not required as the initial SiC substrate 31 can be already highly doped and therefore electrically conductive. On this substrate, an undoped SiC layer 32 can be epitaxially grown and then used as the native layer for growth of the bilayer graphene 15. Back thinning of the highly-doped SiC substrate, formation of a back contact 33, and fabrication of the top of the device can then proceed as described above. In FIG. 4C, a semi-insulating SiC substrate 41 can itself be back-thinned to such a degree as to allow for the direct deposition of a backside metal layer 42. In this embodiment, the backside metal layer 42 can serve as both the back metal reflector and the back-gate contact.

This invention can use any suitable method for producing large area Bernal stacked bilayer graphene films. Epitaxial methods in which graphene is formed atop a SiC substrate, as described above, have been demonstrated to form large areas of high quality BLG necessary for the greatest tunability. See T. Ohta et. al., Phys Rev B 81, 121411 (2010); and K. Lee et al., Nano Letters 11, 3624 (2011), which are incorporated herein by reference. Alternatively, chemical vapor deposition (CVD) techniques are also capable of producing bilayer films but have so far lacked large single crystal domains, which in turn lessens the ability to open up sizable and uniform bandgaps. See S. Lee et al., Nano Letters 10, 4702 (2010). Alternatively, structures similar to those described above can be realized by transferring a Bernal stacked bilayer graphene film from a substrate atop of which growth took place to a host substrate. For example, bilayer graphene growth can take place using any number of means known to those skilled in the art on top of virtually any growth substrate. The BLG films can then be transferred using known transfer technologies and grafted to any host substrate including but not limited to standard silicon wafers. Subsequently, dual gated structures analogous to those described above can be fabricated using the BLG-grafted host substrate.

Because BLG is only 2 atoms thick, absorption in the active bilayer material is extremely small (˜5%). See R. R. Nair et al., Science 320, 1308 (2008). Therefore, the present invention uses a resonant sub-wavelength metallic nanoantenna to amplify the absorption via resonant surface mode coupling. The sub-wavelength nanoantenna can elevate the quantum efficiency (QE) of the device by increasing the electric field strength in the plane of the BLG. This is the result of the nanoantenna coupling incident plane waves of light to surface modes that themselves have extremely concentrated electric fields.

These concentrated electric fields, in turn, create an amplified number of evanescent photons that serve to increase the total absorption within the sensor. See T. J. Echtermeyer et al., Nat Commun 2, 458 (2011), which is incorporated herein by reference. The fields are stronger than those that can reasonably be achieved with a Fabry-Perot type of structure with a similar bandwidth. Moreover, the sub-wavelength antenna structure is angularly independent, unlike a Fabry-Perot device. These nanoantennas also have an advantage over simple plasmonic coupling structures, such as arrays of holes in a metal surface, by having the ability to change the bandwidth and center wavelength through geometrical changes to the antenna finger spacing.

The present invention has been described as a photodetector with an interdigitated nanoelectrode grating antenna. It will be understood that the above description is merely illustrative of the applications of the principles of the present invention, the scope of which is to be determined by the claims viewed in light of the specification. Other variants and modifications of the invention will be apparent to those of skill in the art.

We claim:

1. A photodetector, comprising:
a two-dimensional semiconducting active layer on a substrate;
interdigitated source and drain terminals comprising a periodic array of pairs of source and drain fingers deposited on the front side of the active layer;
a gate dielectric layer deposited on front side of the active layer and the interdigitated source and drain terminals;
a top-gate terminal deposited on the gate dielectric layer, the top-gate terminal comprising a periodic array of gate fingers, each gate finger disposed between a pair of source and drain fingers and thereby forming a channel region therebetween, wherein the gate fingers are electrically connected; and
wherein the interdigitated source and drain terminals, gate dielectric layer and top-gate terminal are adapted to enhance absorption of incident light in the active layer, thereby enabling photodetection of the incident light.

2. The photodetector of claim 1, wherein the periodic array of pairs of source and drain fingers has a periodicity of less than one-third the wavelength of the incident light.

3. The photodetector of claim 1, wherein the incident light has a wavelength between 300 nanometers and 30 microns.

4. The photodetector of claim 1, wherein the width of the channel region formed between each pair of source and drain fingers is less than 10 μm.

5. The photodetector of claim 1, wherein the active layer comprises bilayer graphene.

6. The photodetector of claim 5, wherein the bandgap of the bilayer graphene is tunable from the mid-infrared to terahertz regime of the incident light.

7. The photodetector of claim 1, wherein the active layer comprises molybdenum disulphide, tungsten disulphide, or gallium selenide.

8. The photodetector of claim 1, wherein the thickness of the gate dielectric layer is less than 150 nanometers.

9. The photodetector of claim 1, wherein the gate dielectric layer comprises SiO₂, Al₂O₃₇ Si₃N₄, or HfO₂.

10. The photodetector of claim 1, further comprising a conductive back gate disposed on the backside and insulated from the active layer for applying an electric field with the top-gate terminal across the active layer, thereby forming a dual-gated field-effect transistor.

11. The photodetector of claim 10, wherein the conductive back gate comprises a region of conductive ions implanted in the substrate.

12. The photodetector of claim 1, further comprising a back metal reflector on the back side of the active layer.
